(19) United States
(12) Patent Application Publication
(10) Pub. No.: US 2022/0136679 A1
(43) Pub. Date: May 5, 2022

(54) WAVELENGTH CONVERSION ELEMENT, LIGHT SOURCE DEVICE, VEHICLE HEADLIGHT, TRANSMISSIVE LIGHTING DEVICE, DISPLAY DEVICE, AND LIGHTING DEVICE

(71) Applicant: SHARP KABUSHIKI KAISHA, Sakai City, Osaka (JP)

(72) Inventors: TORU KANNO, Sakai City, Osaka (JP); HIROKAZU ICHINOSE, Sakai City, Osaka (JP); HIDEOMI YUI, Sakai City, Osaka (JP)

(21) Appl. No.: 17/428,250

(22) PCT Filed: Jan. 31, 2020
(86) PCT No.: PCT/JP2020/003686

§ 371 Date: Aug. 3, 2021

(30) Foreign Application Priority Data
Feb. 6, 2019 (JP) 2019-019794

(51) Int. Cl. F21V 9/30; F21S 41/30; F21S 41/176; G02B 26/00; C09K 11/02; C09K 11/77

(52) U.S. Cl. CPC F21V 9/30; F21S 41/30; C09K 11/7774; G02B 26/008; C09K 11/02; F21S 41/176

(57) ABSTRACT

Improvement of the luminous efficiency of a fluorescent layer is achieved. A wavelength conversion element is provided that converts incident, light from a wavelength range thereof to another wavelength range, the wavelength conversion element including a fluorescent layer including first particles and second particles dispersed in a first binder, the second particles being smaller than the first particles, wherein the first particles fluoresce under light having the wavelength of the incident light, and the first binder accounts for from 10% inclusive to 50% exclusive by volume of a particle group including the first particles and the second particles in the fluorescent layer.

The present application claims priority to Japanese Patent Application, Tokugan, No. 2019-19794 filed in Japan on Feb. 6, 2019, which is incorporated herein by reference in its entirety.

### TECHNICAL FIELD

The disclosure relates to wavelength conversion elements used in light source devices, vehicle headlights, transmissive lighting devices, display devices, and lighting devices.

### BACKGROUND ART

In optical elements that fluoresce when excitation light is projected to a phosphor included therein, the phosphor generates heat. In a conventionally known structure of such an optical element, a fluorescent layer is filled with particles of a plurality of sizes to improve the phosphor film density for better heat dissipation.

Patent Literature 1 discloses a wavelength conversion member and a light-emitting device that can suppress transmission of the light emitted by a light source by reducing voids without having to decrease the light conversion efficiency achieved by large-diameter phosphor particles.

### CITATION LIST

### Patent Literature

### Patent Literature 1

PCT International Application Publication No. WO2017/188191 (Publication Date: Nov. 2, 2017)

### SUMMARY OF INVENTION

### Technical Problem

This conventional structure in which a binder binds particles together leaving much empty space, however, entails problems of poor heat dissipation and low phosphor luminous efficiency because transparent ceramics account for such a low proportion that heat primarily conducts through the particles to a substrate where the heat dissipates.

The disclosure, in an aspect thereof, has been made in view of these problems and has an object to improve the luminous efficiency of a fluorescent layer.

### Solution to Problem

To address these problems, the disclosure, in an aspect thereof, is directed to a wavelength conversion element that converts incident light from a wavelength range thereof to another wavelength range, the wavelength conversion element including a fluorescent layer including first particles and second particles dispersed in a first binder, the second particles being smaller than the first particles, wherein the first particles fluoresce under light having the wavelength of the incident light, and the first binder accounts for from 10% inclusive to 50% exclusive by volume of a particle group including the first particles and the second particles in the fluorescent layer.

### Advantageous Effects of Invention

The disclosure, in an aspect thereof, has an advantage of improving the luminous efficiency of a fluorescent layer.

### BRIEF DESCRIPTION OF DRAWINGS

Portion (a) of FIG. 1 is a schematic cross-sectional view of a wavelength conversion element in accordance with Embodiment 1 of the disclosure, and (b) of FIG. 1 is a schematic cross-sectional view of a conventional light-emitting device.

FIG. 2 is a graph representing a particle-size distribution of phosphor particles in the wavelength conversion element in accordance with Embodiment 1 of the disclosure.

FIG. 3 is a schematic cross-sectional view of a variation example of the wavelength conversion element in accordance with Embodiment 1 of the disclosure.

FIG. 4 is a schematic cross-sectional view of a mounting example of the wavelength conversion element in accordance with Embodiment 1 of the disclosure.

FIG. 5 is a schematic cross-sectional view of a wavelength conversion element in accordance with Embodiment 2 of the disclosure.

FIG. 6 is a graph representing temperature dependency of the luminous efficiency of a phosphor.

Portions (a) and (b) of FIG. 7 are schematic cross-sectional views of a wavelength conversion element in accordance with Embodiment 3 of the disclosure, and (c) of FIG. 7 is a schematic cross-sectional view of a wavelength conversion element in accordance with a comparative example.

FIG. 8 is a schematic cross-sectional view of a wavelength conversion element in accordance with Embodiment 4 of the disclosure.

FIG. 9 is a graph representing a particle-size distribution of particles in the wavelength conversion element in accordance with Embodiment 4 of the disclosure.

FIG. 10 is a schematic cross-sectional view of a wavelength conversion element in accordance with Embodiment 5 of the disclosure.

FIG. 11 is a schematic cross-sectional view of a wavelength conversion element in accordance with Embodiment 6 of the disclosure.

FIG. 12 is a schematic cross-sectional view of the wavelength conversion element in accordance with Embodiment 6 of the disclosure.

FIG. 13 is a schematic cross-sectional view of the wavelength conversion element in accordance with Embodiment 6 of the disclosure.

FIG. 14 is a schematic cross-sectional view of the wavelength conversion element in accordance with Embodiment 6 of the disclosure.

FIG. 15 is a schematic diagram of a light source device in accordance with Embodiment 7 of the disclosure.

FIG. 16 is a schematic diagram of a light source device in accordance with Embodiment 8 of the disclosure.

Portion (a) of FIG. 17 is a schematic diagram of a display device in accordance with Embodiment 9 of the disclosure, (b) of FIG. 17 is a schematic plan view of a fluorescent wheel, and (c) of FIG. 17 is a schematic side view of the fluorescent wheel.

FIG. 18 is a schematic cross-sectional view of a light source device 9 in accordance with Embodiment 10 of the disclosure.

### DESCRIPTION OF EMBODIMENTS

### Embodiment 1

The following will describe an embodiment of the disclosure in detail.

Portion (a) of FIG. 1 is a schematic cross-sectional view of a wavelength conversion element in accordance with Embodiment 1 of the disclosure. For the purpose of comparison with a structure in accordance with Embodiment 1 of the disclosure, (b) of FIG. 1 schematically shows a light-emitting device in accordance with conventional art.

Comparison with Conventional Art

As shown in (b) of FIG. 1, a conventional light-emitting device 1b includes phosphor particles on a substrate 13. The phosphor particles include first particles 10 and second particles 11 that are smaller than the first particles 10. In the conventional art disclosed in Patent Literature 1, the particles are bound together by a transparent ceramic. The conventional light-emitting device 1b includes a low proportion of transparent ceramic and exhibits poor heat dissipation.

A fluorescent layer 19b containing a small amount of binder allows the phosphor to come into contact with a void (air) at many points and hence exhibits poor heat dissipation. It is therefore preferable to substitute a material that has a higher thermal conductivity than voids for the non-phosphor portion. It is more preferable if the material has a higher thermal conductivity than the phosphor material. The material is preferably a high thermal conductivity binder composed primarily of an inorganic material such as an aluminum compound for efficient heat transfer. The binder is preferably composed primarily of, for example, alumina or boehmite among other aluminum compounds.

The following is a list of the thermal conductivities at normal temperature of major materials used in the wavelength conversion element.

TABLE 1

| Material | Thermal Conductivity (W/mK) |
|---|---|
| YAG:Ce Phosphor | 12 |
| Air | 0.026 |
| Silicone Resin | 0.2 to 0.4 |
| Silica | 1 to 1.4 |
| TiO₂ | 2 to 4 |
| Alumina | 25 to 30 |

Assuming that the phosphor particles have a completely spherical shape and also that all the phosphor particles have a single particle diameter, the phosphor will have a density of approximately 74% (≈π/√18) in highest density fill. The limit will be approximately 1−(1−π/√18)\hat{ }2≈93% in multi-sphere models. In reality, the phosphor particles do not have a completely spherical shape and are located non-periodically and randomly. The phosphor is thus inferred to account for a maximum of 90% or less of the fluorescent layer by volume. The particle/binder ratio is preferably 0.9 or less. If the binder is less than that, the fluorescence film includes too many voids and exhibits poorer thermal conduction. If the particle/binder ratio is less than 0.1, the particle components in the fluorescence film decrease, and so does the luminous efficiency. The particle/binder ratio is therefore preferably in excess of 0.1.

As shown in (a) of FIG. 1, a wavelength conversion element 1a in accordance with Embodiment 1 of the disclosure includes a fluorescent layer 19a in which the first particles (phosphor particles) 10 and the second particles 11 that are smaller than the first particles 10 are dispersed in a binder 12 (the binder 12 used in the fluorescent layer may be alternatively referred to as the “first binder”). In a preferred embodiment, the fluorescent layer 19a is disposed on the substrate 13.

The first particles 10 and the second particles 11 fluoresce under light that has the same wavelength as the incident light, thereby converting the incident light from a wavelength range to another. The binder 12 and the particle group including the first particles 10 and the second particles 11 preferably have a volume ratio of greater than or equal to 10% and less than 50% in the fluorescent layer 19a.

A preferred example of the fluorescent layer 19a has a thickness of 50 μm and includes the first particles 10 and the second particles 11 both of a yellow phosphor such as YAG:Ce. YAG:Ce is a Ce (cerium)-doped yttrium aluminum garnet phosphor, for example, Y₃Al₅O₁₂:Ce³⁺. The binder 12 is preferably composed primarily of an inorganic alumina. The first particles 10 preferably have an average particle diameter D50 of 25 μm, and the second particles 11 preferably have an average particle diameter D50 of 5 μm. The mix ratio of the first particles 10, the second particles 11, and the binder 12 is preferably 50%:30%:20% by volume.

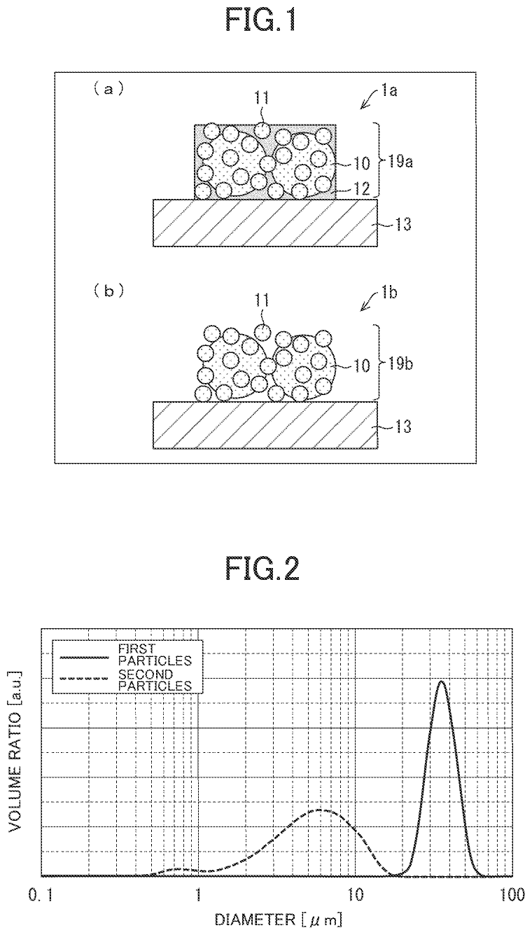

The first particles (phosphor particles) 10 preferably have particle diameters of approximately 10 to 30 μm, and the second particles (phosphor particles) 11 preferably have particle diameters of approximately 1 to 10 μm. The particle diameters of the first particles 10 differ from the particle diameters of the second particles 11 preferably by a factor of at least 2, more preferably by a factor of at least 3. The particles are not necessarily, for example, spherical or elliptical. FIG. 2 shows a particle-size distribution of the phosphor particles in accordance with present Embodiment 1. In FIG. 2, the horizontal axis represents the particle diameter, and the vertical axis represents the volume ratio. Referring to FIG. 2, the particle-size distribution is characterized by having two distinct peaks. The particle-size distribution of a phosphor can be measured, for example, using a laser diffraction/scattering device LA-950 manufactured by Horiba, Ltd. after separating the binder 12 and the particles in a suitable manner. The LA-950 device operates by static light scattering.

### Variation Examples

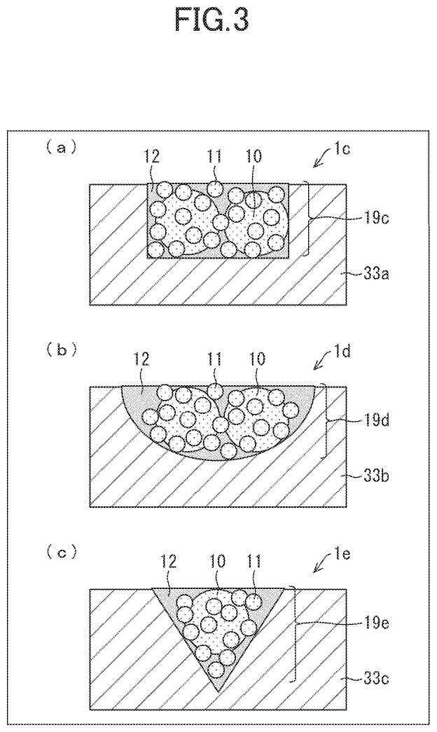

The fluorescent layer 19a is disposed on the substrate 13 in the typical aspect of the disclosure described above with reference to (a) of FIG. 1. The wavelength conversion element in accordance with the disclosure is not necessarily limited to such an aspect and may be reduced to practice in various other forms shown in, for example, FIG. 3. FIG. 3 is a schematic cross-sectional view of wavelength conversion elements 1c to 1e that are variation examples of the wavelength conversion element 1a in accordance with Embodiment 1 of the disclosure. Portion (a) of FIG. 3 shows the wavelength conversion element 1c including a fluorescent layer 19c in a substrate 33a in which there is formed a groove that has a rectangular cross-sectional shape. Portion (b) of FIG. 3 shows the wavelength conversion element 1d including a fluorescent layer 19d in a substrate 33b in which there is formed a groove that has an arc-like cross-sectional shape. Portion (c) of FIG. 3 shows the wavelength conversion element 1e including a fluorescent layer 19e in a substrate 33c in which there is formed a groove that has a V-shaped cross-sectional shape. The fluorescent layers 19d to 19e are preferably the same as the fluorescent layer 19a shown in (a) of FIG. 1, but differ in the locations thereof relative to the substrate.

### Mounting Example

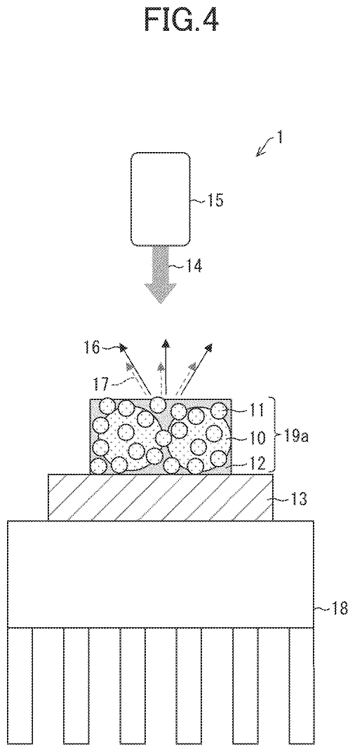

FIG. 4 is a schematic diagram of an example where the wavelength conversion element is being mounted in accordance with Embodiment 1 of the disclosure. FIG. 4 shows as an example an aspect of the invention in which the wavelength conversion element 1a shown as an example in (a) of FIG. 1 is disposed on a heatsink 18. The wavelength conversion elements 1c to 1e of the variation examples may be disposed on the heatsink 18.

The fluorescent layer 19a is preferably manufactured by, for example, screen printing. The substrate 13 is preferably composed of, for example, an aluminum substrate or a highly reflective alumina substrate. The substrate 13 is preferably a metal or like substance that exhibits a high thermal conductivity, but is not necessarily limited to these examples. The substrate 13 is preferably coated with a high reflective film of, for example, silver, titanium oxide, reflection-enhancing multilayered film, or dielectric mirror, to enhance the intensity of fluorescence. It is also preferable to provide a scattering layer 100 on the substrate 13 as will be detailed later in Embodiment 6. When the fluorescent layer is not provided directly on the substrate 13, for example, when the scattering layer 100 and/or a coating are(is) interposed between the fluorescent layer and the substrate 13, the disclosure, in an aspect thereof, still uses the nomenclature “substrate 13” and may alternatively refer to the substrate 13 as an underlying layer. The substrate 13 is cooled in fixed direct contact with the heatsink 18.

Referring to FIG. 4, a light source device 1 to which a wavelength conversion element is mounted includes: a light source 15 for emitting excitation light 14; and the wavelength conversion element 1a on the heatsink 18. The light source 15 is preferably a light source for emitting blue excitation light such as a blue laser device or a blue LED.

The excitation light 14, emitted by the light source 15, is shone onto the fluorescent layer 19a and partially diffuse-reflected off the surface of the fluorescent layer 19a, forming reflected light 17. Meanwhile, the excitation light 14 partially enters the fluorescent layer 19a and induces fluorescence through interaction with the phosphor particles. This fluorescence exits the fluorescent layer 19a as fluorescence 16.

### Embodiment 2

The following will describe another embodiment of the disclosure. For convenience of description, members of the present embodiment that have the same function as members of the preceding embodiment are indicated by the same reference numerals, and description thereof is not repeated.

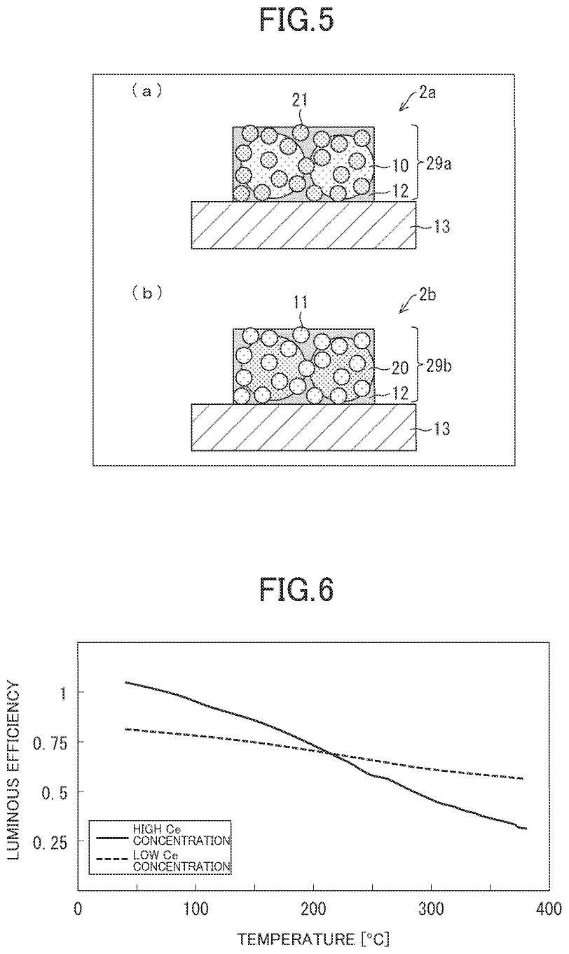

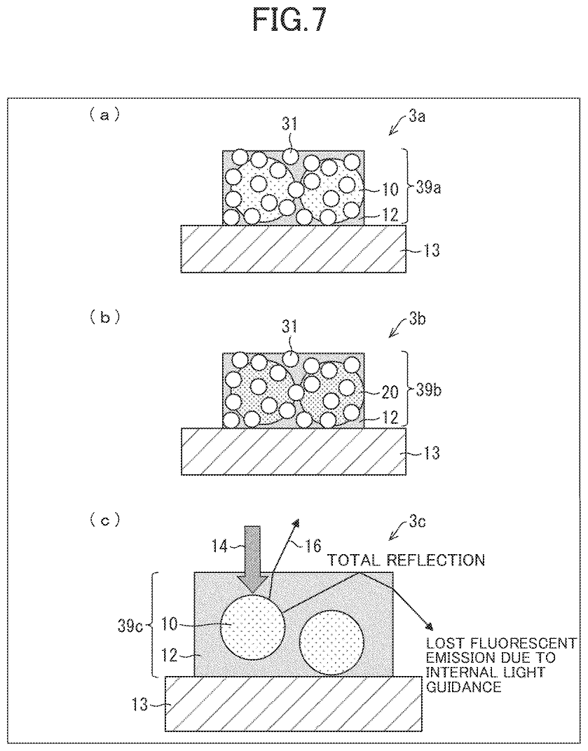

FIG. 5 is a schematic cross-sectional view of a wavelength conversion element in accordance with Embodiment 2 of the disclosure. FIG. 6 is a graph representing temperature dependency of the luminous efficiency of a phosphor.

### Temperature Dependency of Luminous Efficiency

A description is given of the temperature dependency of the luminous efficiency of a phosphor, based on the external quantum efficiency of YAG:Ce (Y₃Al₅O₁₂:Ce³⁺) phosphor. FIG. 6 demonstrates that the luminous efficiency of a phosphor material (Ce-doped YAG) has temperature dependency that is variable with Ce doping concentration. The Ce doping concentration (mol %) in an aspect of the disclosure is given by x×100 (mol %) for a substance of general formula (M₁₋ₓREₓ)₃Al₅O₁₂, which is a general formula for a garnet-based phosphor, where M and RE each include at least one element selected from the rare-earth elements. M is typically at least one of Sc, Y, Gd, and Lu elements. RE is typically at least one of Ce, Eu, and Tb elements.

When excitation light is projected to a phosphor, the phosphor fluoresces, and some of the excitation light turns into thermal energy. The irradiated spot on the phosphor therefore has high temperature. Heat radiation can be generally explained using the following formula:

Q=A·ε·σ·(T_{A}\hat{ }4−T_{B}\hat{ }4)

where Q is the quantity of radiation heat, A is the area of a radiation region, ε is an emissivity, σ is the Stefan-Boltzmann constant, T_{A} is the temperature of the radiation region, and T_{B} is the temperature of the surroundings.

It is known that the luminous efficiency of a phosphor is affected by the temperature of the phosphor. The luminous efficiency decreases with increasing temperature as shown in FIG. 6. The radiation intensity of the excitation light 14 needs to be increased to produce more intense (brighter) fluorescence. However, the fluorescent layer may not be sufficiently prevented from increasing in temperature, depending on cooling conditions.

It is also known that the phosphor has temperature characteristics that vary with the concentration of the luminescence-center element (Ce in the present embodiment). YAG:Ce phosphors commonly available on the market often have such a Ce concentration that the YAG:Ce phosphors can exhibit a high luminous efficiency when used at normal temperature (e.g., approximately 1.4 to 1.5 mol %). This is because the YAG phosphor with a low Ce concentration has a relatively high internal quantum efficiency, but a relatively low excitation light absorptance, and hence the external quantum efficiency, which is an important property of the wavelength conversion element, is optimal near the Ce concentration of 1.5 mol %. A common YAG:Ce phosphor (e.g., Ce concentration=1.4 mol %) will decrease in luminous efficiency (see FIG. 6) when the temperature of the phosphor at the irradiated spot rises beyond 250° C. under high density, high intensity excitation light radiation. However, the YAG:Ce phosphor with a low Ce concentration (e.g., approximately 0.3 mol %) exhibits low temperature dependency of luminous efficiency and may in some cases exhibit a higher luminous efficiency than a luminous body with a high concentration at high temperature. For instance, compare the curves in the graph in FIG. 6 in a low temperature range (50° C. to 100° C.) and in a high temperature range (250° C. to 350° C.). YAG:Ce phosphor with a high Ce concentration tends to exhibit a higher luminous efficiency in the low temperature range, whereas YAG:Ce phosphor with a low Ce concentration tends to exhibit a higher luminous efficiency in the high temperature range. A description will be given of the disclosure for each embodiment thereof in view of this tendency.

Incidentally, phosphors having a low luminescence-center element concentration undesirably have such a low excitation light absorptance that the phosphors cannot absorb sufficient excitation light.

When a laser beam is projected for excitation, it is preferable to use a highly heat-resistant oxynitride-based or nitride-based phosphor because the excitation density increases and hence the temperature rises. A desirable phosphor exhibits good temperature dependency of luminous efficiency. In addition, to use the phosphor in a light source device, the fluorescence may be non-white light such as blue, green, or red light.

Near-ultraviolet light may be converted to red light using a phosphor such as CaAlSiN₃:Eu²⁺. Near-ultraviolet light may be converted to yellow light using a phosphor such as Ca-α-SiAlON:Eu²⁺. Near-ultraviolet light may be converted to green light using a phosphor such as β-SiAlON:Eu²⁺ or Lu₃Al₅O₁₂:Ce³⁺ (LuAG:Ce). Near-ultraviolet light may be converted to blue light using a phosphor such as (Sr,Ca,Ba,Mg)₁₀(PO₄)₆C₁₂:Eu, BaMgAl₁₀O₁₇:Eu²⁺, or (Sr,Ba)₃MgSi₂O₈:Eu²⁺.

A fluorescent member may be formed so as to include two phosphors capable of converting near ultraviolet excitation light to yellow light and blue light respectively. This particular structure enables mixing yellow and blue fluorescence emitted by the fluorescent member for quasi-white light.

### Fluorescent Layer Containing Mixture of Phosphors Having Different Luminescence-center Element Concentrations

In view of the temperature dependency of the luminous efficiency of phosphors described above, a description is given below of an aspect of the invention in which there are provided first and second phosphor particles that have different luminescence-center element concentrations.

Portion (a) of FIG. 5 shows a wavelength conversion element 2a with a fluorescent layer 29a including the same first particles 10 as in Embodiment 1 and further including second particles 21 that have a higher luminescence-center element concentration than the first particles 10. Portion (b) of FIG. 5 shows a wavelength conversion element 2b with a fluorescent layer 29b including the same second particles 11 as in Embodiment 1 and further including first particles 20 that have a higher luminescence-center element concentration than the second particles 11.

The fluorescent layer 29a shown in (a) of FIG. 5 preferably has a thickness of, for example, approximately 50 μm. Preferably, the first particles 10 are a YAG:Ce phosphor as in Embodiment 1 and have an average particle diameter D50 of approximately 25 μm. The first particles 10 preferably have a Ce (dopant) concentration of 0.7 mol % (approximately 0.5 to 1.0 mol %).

Meanwhile, preferably, the second particles 21 are a YAG:Ce phosphor and have an average particle diameter D50 of approximately 5 μm. The second particles 21 preferably have a Ce (dopant) concentration of 1.5 mol % (approximately 1.0 to 2.0 mol %).

The binder 12 in the fluorescent layer 29a is preferably composed primarily of an inorganic alumina binder, but not necessarily so. The first particles 10, the second particles 21, and the binder 12 in the fluorescent layer 29a preferably have a composition ratio of, for example, 50%:30%:20% by volume.

The fluorescent layer 29b shown in (b) of FIG. 5 preferably has a thickness of approximately 50 μm similarly to the fluorescent layer 29a. Preferably, the first particles 20 are a YAG:Ce phosphor and have an average particle diameter D50 of approximately 25 μm. The first particles 20 preferably have a Ce (dopant) concentration of 1.5 mol % (approximately 1.0 to 2.0 mol %).

Meanwhile, preferably, the second particles 11 are a YAG:Ce phosphor as in Embodiment 1 and have an average particle diameter D50 of approximately 5 μm. The second particles 11 preferably have a Ce (dopant) concentration of 0.7 mol % (approximately 0.5 to 1.0 mol %).

The binder 12 in the fluorescent layer 29b is preferably composed primarily of an inorganic alumina binder similarly to the fluorescent layer 29a, but not necessarily so. The first particles 20, the second particles 11, and the binder 12 in the fluorescent layer 29b preferably have a composition ratio of, for example, 50%:30%:20% by volume.

Phosphor particles with a small particle diameter exhibit a low absorptance for the excitation light 14. In contrast, a YAG:Ce phosphor with a high Ce (dopant) concentration exhibit a high absorptance for the excitation light 14. The external quantum efficiency of a YAG:Ce phosphor varies with the particle diameter and Ce concentration of the phosphor particles. These variations lead to changes in the absorption and emission of excitation light, hence changes in the color of the emission.

A target color temperature can be readily achieved by adjusting (varying) the Ce (dopant) concentration in the first particles which is a YAG:Ce phosphor and in the second particles which are smaller than the first particles. The Ce concentration may be higher either in the first particles or in the second particles. Whether the Ce concentration is higher in the first particles or in the second particles may be selected appropriately for intended use. The selection is not limited in any particular manner.

### Combinations with Embodiment 1

Embodiment 2 may be combined with Embodiment 1 described earlier.

For instance, the wavelength conversion elements 2a and 2b shown in FIG. 5 are disposed on the substrate 13. Alternatively, the wavelength conversion elements 2a and 2b may be disposed on the substrates 33a to 33c having a groove formed therein as shown in FIG. 3. In addition, the wavelength conversion elements 2a and 2b may be mounted to the light source device 1 shown in FIG. 4.

### Embodiment 3

The following will describe another embodiment of the disclosure. For convenience of description, members of the present embodiment that have the same function as members of the preceding embodiments are indicated by the same reference numerals, and description thereof is not repeated.

Portions (a) and (b) of FIG. 7 are schematic cross-sectional views of a wavelength conversion element in accordance with Embodiment 3 of the disclosure. Portion (c) of FIG. 7 is a schematic cross-sectional view of a wavelength conversion element in accordance with a comparative example.

### Structure in Accordance with Comparative Example

Portion (c) of FIG. 7 schematically shows a wavelength conversion element 3c in accordance with a comparative example. A fluorescent layer 39c in accordance with the comparative example is characterized by including the first particles (phosphor particles) 10, but no second particles smaller than the first particles 10, in the binder 12. Under the excitation light 14, preferably, the first particles (phosphor particles) 10 fluoresce, and the fluorescence 16 exits the wavelength conversion element 3c through the surface through which the excitation light 14 enters the wavelength conversion element 3c. However, as shown in (c) of FIG. 7, when the excitation light 14 is projected to the first particles (phosphor particles) 10, the resultant fluorescence 16 may undergo total reflection at the interface and fail to exit the wavelength conversion element 3c through the surface through which the excitation light 14 enters the wavelength conversion element 3c, depending on the relationship between the curvature of the first particles 10 and the angle of incidence of the excitation light 14, the refractive index of the binder 12, and other conditions. This fluorescence failing to come out is “lost fluorescent emission” (loss) attributable to internal light guidance and hence lowers fluorescence extraction efficiency. Fluorescence extraction efficiency is defined as equal to the “intensity of fluorescence coming out through the surface struck by the excitation light 14” divided by the “intensity of the excitation light” and includes the “efficiency of the excitation light entering the phosphor,” the “luminous efficiency of the phosphor,” and the “efficiency of the fluorescence exiting through the surface struck by the excitation light.”

### Fluorescent Layer Containing Additional, Scattering Particles

As shown in (a) of FIG. 7, a wavelength conversion element 3a in accordance with Embodiment 3 of the disclosure includes a fluorescent layer 39a in which the first particles (phosphor particles) 10 and second particles 31 that are smaller than the first particles 10 are dispersed in the binder 12. The fluorescent layer 39a is disposed on the substrate 13 in a preferred embodiment. Unlike the second particles 11 in accordance with Embodiment 1, the second particles 31 in accordance with present Embodiment 3 are characterized by being capable of scattering light that has the same wavelength as the incident light.

The fluorescent layer 39a shown in (a) of FIG. 7 preferably has a thickness of, for example, approximately 50 μm. Preferably, the first particles 10 are a YAG:Ce phosphor as in Embodiment 1 and have an average particle diameter D50 of approximately 25 μm.

Meanwhile, the second particles 31 need only to be capable of scattering incident light and may be composed primarily of a YAG. The second particles 31 are preferably composed primarily of titanium oxide, silica, zinc oxide, or diamond.

There are several types of light scattering such as geometric-optical scattering, Mie scattering, and Rayleigh scattering. Particularly, it is known that the scattering efficiency of particles with a diameter close to the wavelength of light is a maximum owing to Mie scattering. It is also known that the scattering by such particles does not vary much with wavelength. Therefore, preferably, the scattering particles at least have a particle diameter approximately equal to the wavelength. The second particles 31 may have an average particle diameter D50 of approximately 2 μm in the present embodiment. In a more preferred embodiment, the second particles 31, which scatters light that has the same wavelength as the incident light, preferably have an average particle diameter D50 smaller than the wavelength of the incident light. The second particles 31 more preferably have an average particle diameter D50 of, for example, approximately 200 nm.

The binder 12 in the fluorescent layer 39a is preferably composed primarily of an inorganic alumina binder, but not necessarily so. The first particles 10, the second particles 31, and the binder 12 in the fluorescent layer 39a preferably have a composition ratio of, for example, 50%:30%:20% by volume.

The scattering, second particles 31 scatter the fluorescence that undergoes total reflection at the interface. The second particles 31 thus, in comparison with the fluorescent layer 39c in accordance with the comparative example show in Portion (c) of FIG. 7, can reduce the fluorescence that undergoes total reflection at the interface and travels toward a side face of the fluorescent layer 39a.

The second particles 31 preferably have a hollow therein (“hollow particles”). The hollow has such a low refractive index that light is more likely scattered due to a difference in refractive indices.

### Combinations with Other Embodiments

Embodiment 3 may be combined with Embodiment 1 or 2 described earlier.

For instance, the dopant concentration in the phosphor particles may be varied as described in Embodiment 2.

For instance, the first particles 10 in the fluorescent layer 39a in the wavelength conversion element 3a shown in (a) of FIG. 7 may have a Ce (dopant) concentration of 0.7 mol % (approximately 0.5 to 1.0 mol %). Meanwhile, the first particles 20 in a fluorescent layer 39b in a wavelength conversion element 3b shown in (b) of FIG. 7 may have a Ce (dopant) concentration of 1.5 mol % (approximately 1.0 to 2.0 mol %).

As described earlier in Embodiment 2, an increase in the Ce (dopant) concentration leads to a rise in the temperature of the phosphor particles and hence a decrease in the luminous efficiency thereof. In such a situation, the second particles 31 preferably include many solid particles rather than hollow particles. The inclusion of solid particles enables improving thermal conductivity over a fluorescent layer containing hollow particles, thereby efficiently cooling the fluorescent layer 39b. This structure can hence prevent the burnout of the fluorescent layer 39b and improve the durability of the wavelength conversion element 3b.

Additionally, for instance, the wavelength conversion elements 3a and 3b shown in (a) and (b) of FIG. 7 are disposed on the substrate 13. Alternatively, the wavelength conversion elements 3a and 3b may be disposed on the substrates 33a to 33c having a groove formed therein as shown in FIG. 3. In addition, the wavelength conversion elements 3a and 3b may be mounted to the light source device 1 shown in FIG. 4.

### Embodiment 4

The following will describe another embodiment of the disclosure. For convenience of description, members of the present embodiment that have the same function as members of the preceding embodiments are indicated by the same reference numerals, and description thereof is not repeated.

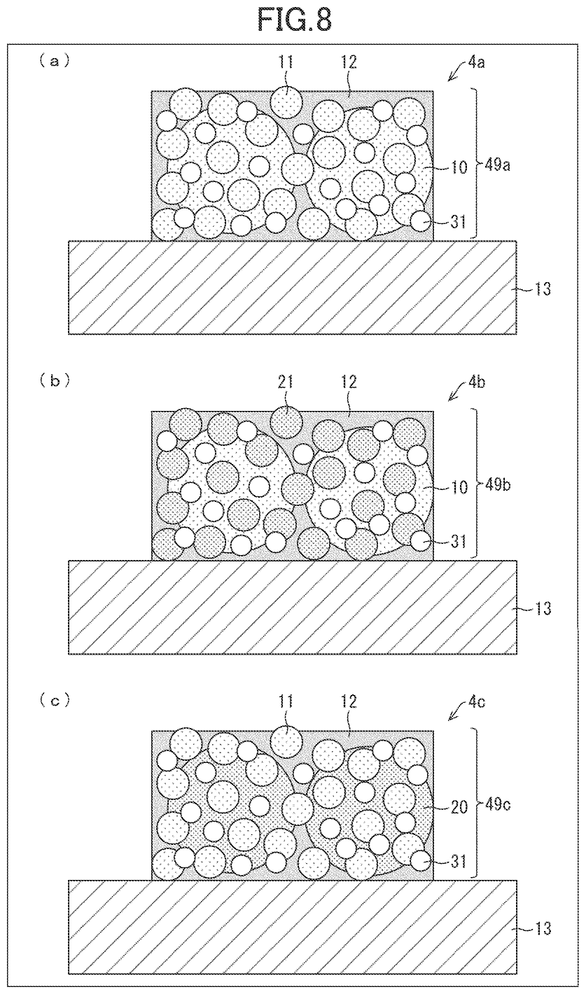

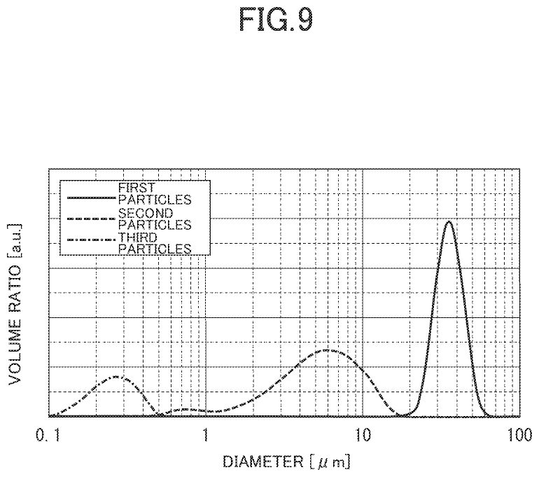

FIG. 8 is a schematic cross-sectional view of a wavelength conversion element in accordance with Embodiment 4 of the disclosure. FIG. 9 is a graph representing a particle-size distribution of particles in the wavelength conversion element in accordance with Embodiment 4 of the disclosure.

### Fluorescent Layer Containing Additional, Scattering Particles

As shown in (a) of FIG. 8, a wavelength conversion element 4a in accordance with Embodiment 4 of the disclosure includes a fluorescent layer 49a in which the first particles (phosphor particles) 10, the second particles 11 that are smaller than the first particles 10, and third particles 31 that are smaller than the second particles 11 are dispersed in the binder 12. The fluorescent layer 49a is disposed on the substrate 13 in a preferred embodiment.

The first particles 10 and the second particles 11 fluoresce under light that has the same wavelength as the incident light, thereby converting the incident light from a wavelength range to another. Similarly to the second particles 31 in accordance with Embodiment 3, the third particles 31 in accordance with present Embodiment 4 are characterized by being capable of scattering the incident light. The third particles 31 in accordance with present Embodiment 4 preferably have the same structure as the second particles 31 in accordance with Embodiment 3. The first particles 10, the second particles 11, and the binder 12 in accordance with present Embodiment 4 preferably have the same structure as the first particles 10, the second particles 11, and the binder 12 in accordance with Embodiment 1.

A preferred example of the fluorescent layer 49a has a thickness of 50 μm and includes the first particles 10 and the second particles 11 both of a yellow phosphor such as YAG:Ce. The scattering, third particles 31 are preferably composed primarily of titanium oxide, silica, zinc oxide, or diamond.

The binder 12 is preferably composed primarily of an inorganic alumina, but not necessarily so. The first particles 10, the second particles 11, the third particles 31, and the binder 12 in the fluorescent layer 49a preferably have a composition ratio of, for example, 50%:20%:10%:20% by volume.

The first particles 10 preferably have an average particle diameter D50 of 25 μm. The second particles 11 preferably have an average particle diameter D50 of 5 μm. The third particles 31 preferably have an average particle diameter D50 of 0.2 μm.

FIG. 9 shows a particle-size distribution of particles for present Embodiment 4. In FIG. 9, the horizontal axis represents the diameter of the particles, and the vertical axis represents the volume ratio thereof. Referring to FIG. 9, the particle-size distribution is characterized by having three distinct peaks. The particle-size distribution of a phosphor can be measured, for example, using a laser diffraction/scattering device LA-950 manufactured by Horiba, Ltd. after separating the binder and the particles in a suitable manner. The LA-950 device operates by static light scattering.

Phosphors with a larger particle diameter exhibit a higher luminous efficiency. As the particle diameter decreases approximately to the submicron level, the luminous efficiency falls abruptly. It is therefore preferable to add as the second particles 11 a phosphor that has a particle diameter no smaller than a few micrometers.

The addition of the third particles 31 in present Embodiment 4 enhances scattering inside the fluorescent layer 49a, thereby improving fluorescent extraction efficiency for the surface struck by incident light, as in Embodiment 3.

### Combinations with Other Embodiments

Embodiment 4 may be combined with Embodiments 1 to 3 described earlier.

For instance, the dopant concentration in the phosphor particles may be varied as described in Embodiment 2.

For instance, the first particles 10 of YAG:Ce in a fluorescent layer 49b in a wavelength conversion element 4b shown in (b) of FIG. 8 may have a Ce (dopant) concentration of 0.7 mol % (approximately 0.5 to 1.0 mol %). The second particles 21 of YAG:Ce in the fluorescent layer 49b preferably have a Ce (dopant) concentration of 1.5 mol % (approximately 1.0 to 2.0 mol %) as in Embodiment 2.

Meanwhile, the first particles 20 of YAG:Ce in a fluorescent layer 49c in a wavelength conversion element 4c shown in (c) of FIG. 8 may have a Ce (dopant) concentration of 1.5 mol % (approximately 1.0 to 2.0 mol %). The second particles 11 of YAG:Ce in the fluorescent layer 49b preferably have a Ce (dopant) concentration of 0.7 mol % (approximately 0.5 to 1.0 mol %) as in Embodiment 2.

As described earlier in Embodiment 2, an increase in the Ce (dopant) concentration leads to a rise in the temperature of the phosphor particles and hence a decrease in the luminous efficiency thereof. In such a situation, the third particles 31 preferably include many solid particles of titanium oxide rather than hollow particles. The inclusion of solid particles enables improving thermal conductivity over a fluorescent layer containing hollow particles, thereby efficiently cooling the fluorescent layers 49b and 49c. This structure can hence prevent the burnout of the fluorescent layers 49b and 49c and improve the durability of the wavelength conversion elements 4b and 4c.

Additionally, for instance, the wavelength conversion elements 4a to 4c shown in FIG. 8 are disposed on the substrate 13. Alternatively, the wavelength conversion elements 4a to 4c may be disposed on the substrates 33a to 33c having a groove formed therein as shown in FIG. 3. In addition, the wavelength conversion elements 4a to 4c may be mounted to the light source device 1 shown in FIG. 4.

### Embodiment 5

The following will describe another embodiment of the disclosure. For convenience of description, members of the present embodiment that have the same function as members of the preceding embodiments are indicated by the same reference numerals, and description thereof is not repeated.

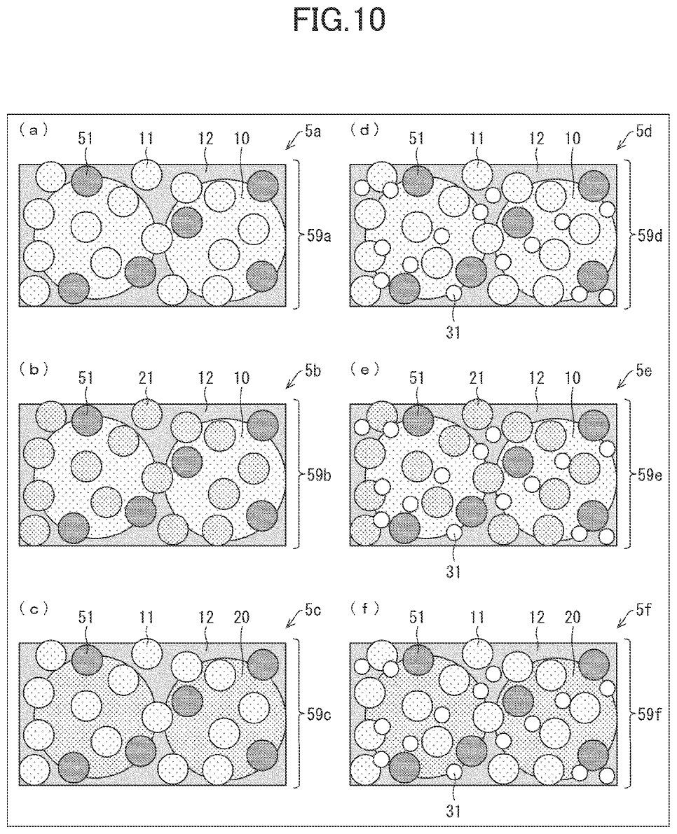

FIG. 10 is a schematic cross-sectional view of a wavelength conversion element in accordance with Embodiment 5 of the disclosure.

### Fluorescent Layer Containing Mixture of Particles of Different Phosphor Species

As shown in (a) of FIG. 10, a wavelength conversion element 5a in accordance with Embodiment 5 of the disclosure includes a fluorescent layer 59a in which the first particles (phosphor particles) 10, the second particles 11 that are smaller than the first particles 10, and fourth particles 51 that are smaller than the first particles are dispersed in the binder 12. The fluorescent layer 59a is preferably disposed on the substrate 13 (not shown in FIG. 10) as in Embodiments 1 to 4 described earlier.

The fourth particles fluoresce at different wavelengths from the wavelengths at which the first particles fluoresce under the incident light of the foregoing wavelengths.

A preferred example of the fluorescent layer 59a has a thickness of 50 μm and includes the first particles 10 and the second particles 11 both of a yellow phosphor such as YAG:Ce (Y₃Al₅O₁₂:Ce³⁺). The fourth particles 51, which have different fluorescence properties than YAG, is preferably composed primarily of CASN (CaAlSiN₃:Eu²⁺).

The binder 12 is preferably composed primarily of an inorganic alumina, but not necessarily so. The first particles 10, the second particles 11, the fourth particles 51, and the binder 12 in the fluorescent layer 59a preferably have a composition ratio of, for example, 50%:20%:10%:20% by volume.

The first particles 10 preferably have an average particle diameter D50 of 25 μm. The second particles 11 preferably have an average particle diameter D50 of 5 μm. The fourth particles 51 preferably have an average particle diameter D50 of 5 μm.

The addition of the fourth particles 51 of CASN (CaAlSiN3:Eu²⁺) in present Embodiment 5 can provide a red fluorescent component. The mixing of different phosphor species can vary the color of the emission of the fluorescent layer 59a.

Suitable phosphors may be used to provide necessary colors. As an example, CaAlSiN₃:Eu²⁺ may be used as a phosphor for converting near-ultraviolet light to red light. As an example, Ca-α-SiAlON:Eu²⁺ may be used as a phosphor for converting near-ultraviolet light to yellow light. As an example, β-SiAlON:Eu²⁺ or Lu₃Al₅O₁₂:Ce³⁺ (LuAG:Ce) may be used as a phosphor for converting near-ultraviolet light to green light. As an example, (Sr,Ca,Ba,Mg)₁₀ (PO₄)₆C₁₂:Eu, BaMgAl₁₀O₁₇:Eu²⁺, or (Sr,Ba)₃MgSi₂O₈:Eu²⁺ may be used as a phosphor for converting near-ultraviolet light to blue light.

### Combinations with Other Embodiments

Embodiment 5 may be combined with Embodiments 1 to 4 described earlier.

For instance, the dopant concentration in the phosphor particles may be varied as described in Embodiment 2.

For instance, the first particles 10 of YAG:Ce in a fluorescent layer 59b in a wavelength conversion element 5b shown in (b) of FIG. 10 may have a Ce (dopant) concentration of 0.7 mol % (approximately, 0.5 to 1.0 mol %). The second particles 21 of YAG:Ce in the fluorescent layer 59b preferably have a Ce (dopant) concentration of 1.5 mol % (approximately 1.0 to 2.0 mol %) as in Embodiment 2.

Meanwhile, the first particles 20 of YAG:Ce in a fluorescent layer 59c in a wavelength conversion element 5c shown in (c) of FIG. 10 may have a Ce (dopant) concentration of 1.5 mol % (approximately 1.0 to 2.0 mol %). The second particles 11 of YAG:Ce in the fluorescent layer 49b preferably have a Ce (dopant) concentration of 0.7 mol % (approximately 0.5 to 1.0 mol %) as in Embodiment 2.

The addition of the fourth particles 51 in present Embodiment 5 can provide a red fluorescent component to Embodiment 2. As described in Embodiment 2, an increase in the Ce (dopant) concentration leads to a rise in the temperature of the phosphor particles and hence a decrease in the luminous efficiency thereof. The mixing of different phosphor species enables adjusting the luminous efficiency and temperature as well as varying the color of the emission of the fluorescent layers 59b and 59c.

As described in Embodiment 4, similarly to the second particles 31 in accordance with Embodiment 3, the third particles 31, which scatter incident light of wavelengths given in present Embodiment 5, may be further included in present Embodiment 5 (see (d) to (f) of FIG. 10).

A wavelength conversion element 5d shown in (d) of FIG. 10 has the same structure as the wavelength conversion element 5a shown in (a) of FIG. 10, except that the former further includes the third particles 31. Likewise, a wavelength conversion element 5e shown in (e) of FIG. 10 has the same structure as the wavelength conversion element 5b shown in (b) of FIG. 10, except that the former further includes the third particles 31. A wavelength conversion element 5f shown in (f) of FIG. 10 has the same structure as the wavelength conversion element 5c shown in (c) of FIG. 10, except that the former further includes the third particles 31.

The aspects of the invention shown in (d) to (f) of FIG. 10 can enhance scattering inside fluorescent layers 59d to 59f, thereby improving fluorescent extraction efficiency for the surface struck by incident light, as in Embodiments 3 and 4.

Additionally, for instance, the wavelength conversion elements 5a to 5f shown in FIG. 10 may be disposed on the substrate 13. Alternatively, the wavelength conversion elements 5a to 5f may be disposed on the substrates 33a to 33c having a groove formed therein as shown in FIG. 3. In addition, the wavelength conversion elements 5a to 5f may be mounted to the light source device 1 shown in FIG. 4.

### Embodiment 6

The following will describe another embodiment of the disclosure. For convenience of description, members of the present embodiment that have the same function as members of the preceding embodiments are indicated by the same reference numerals, and description thereof is not repeated.

### Structure of Wavelength Conversion Element

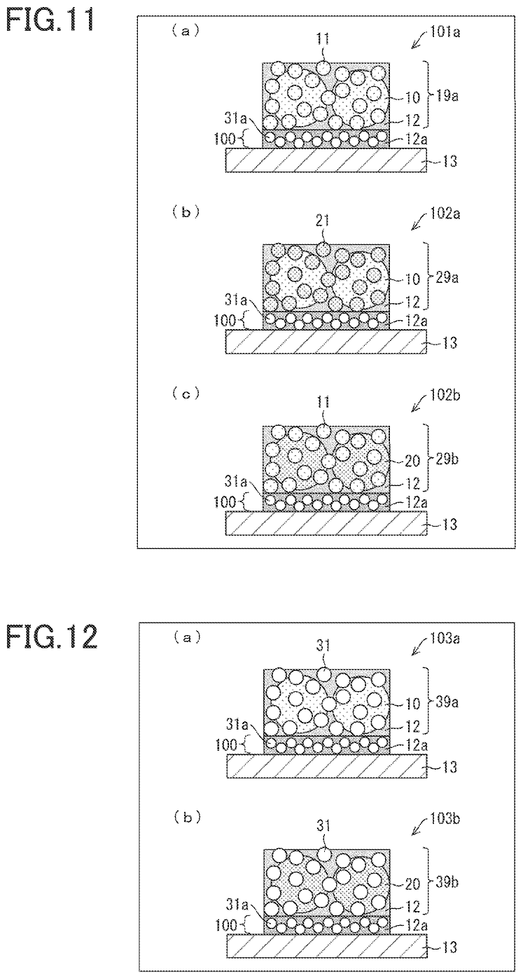

FIGS. 11 to 14 are schematic cross-sectional views of a structure of a wavelength conversion element in accordance with Embodiment 6 of the disclosure.

The wavelength conversion element in accordance with the present embodiment includes a fluorescent layer disposed in such a manner that the fluorescent layer faces an underlying layer and further includes a scattering layer 100 between the substrate (underlying layer) 13 and the fluorescent layers 19a, 29a, 29b, 39a, 39b, 49a, 49b, 49c, 59a, 59b, 59c, 59d, 59e, or 59f.

### Scattering Layer 100

The scattering layer 100 includes a binder 12a and scattering particles 31a dispersed in the binder 12a (the binder 12a used in the scattering layer may be alternatively referred to as the “second binder”). The binder 12a preferably has the same structure as the binder 12 described above, but may have a different structure. The scattering particles 31a preferably have a higher refractive index than the first particles 10 and 20, the second particles 11 and 21, the fourth particles 51, and the binder 12a. The scattering particles 31a in accordance with present Embodiment 6 preferably have the same structure as the third particles 31 in accordance with Embodiment 4.

The provision of the scattering layer 100 including the scattering particles 31a having a high refractive index between the substrate 13 and the fluorescent layers 19a, 29a, 29b, 39a, 39b, 49a, 49b, 49c, 59a, 59b, 59c, 59d, 59e, and 59f enables the fluorescence travelling in the opposite direction from the extraction surface to be scattered and re-directed toward the extraction surface, thereby restraining fluorescence loss attributable to light guidance. Furthermore, since the scattering layer 100 scatters the excitation light 14 which enters the fluorescent layer, but transmits through the fluorescent layers 19a, 29a, 29b, 39a, 39b, 49a, 49b, 49c, 59a, 59b, 59c, 59d, 59e, and 59f without directly contributing to the fluorescence of the phosphor particles (first particles 10 and 20, second particles 11 and 21, and fourth particles 51), the length of the optical path of the excitation light 14 is increased, which can in turn improve the use efficiency of the excitation light 14. The provision of the scattering layer 100 can therefore increase the intensity of fluorescence.

The fluorescent layers 19a, 29a, 29b, 39a, 39b, 49a, 49b, 49c, 59a, 59b, 59c, 59d, 59e, and 59f can be thinner than in the wavelength conversion elements that have the same intensity of fluorescence, which translates into a reduced requisite quantity of phosphor particles (first particles 10 and 20, second particles 11 and 21, and fourth particles 51). In this context, the “extraction surface” refers to the opposite surface (bottom face) of the fluorescent layer from the surface thereof where the fluorescent layer is in contact with the scattering layer. The “opposite direction from the extraction surface” refers to the direction toward this contact surface or a side face of the fluorescent layer.

The scattering particles 31a are preferably composed primarily of titanium oxide (TiO₂), silica, zinc oxide (ZnO), or diamond and are especially preferably titanium oxide. The titanium oxide preferably has a rutile crystal structure.

The scattering particles 31a preferably account for approximately 10 to 75 vol % of the scattering layer 100. This particular composition can achieve the aforementioned advantages while preserving adherence to the substrate 13.

The scattering layer 100 preferably has a thickness of 20 to 60 μm.

### Combinations with Other Embodiments

Embodiment 6 may be combined with Embodiments 1 to 5 described earlier.

Portion (a) of FIG. 11 shows an exemplary combination with Embodiment 1. A wavelength conversion element 101a includes the fluorescent layer 19a in which the first particles (phosphor particles) 10 and the second particles 11 that are smaller than the first particles 10 are dispersed in the binder 12, as in Embodiment 1. The wavelength conversion element 101a further includes the scattering layer 100 between the substrate 13 and the fluorescent layer 19a.

Portions (b) and (c) of FIG. 11 show exemplary combinations with Embodiment 2. Wavelength conversion elements 102a and 102b include the respective fluorescent layers 29a and 29b in which the first particles (phosphor particles) 10 and 20 and the second particles 21 and 11 that are smaller than the first particles 10 and 20 are dispersed in the binder 12, as in Embodiment 2. The wavelength conversion elements 102a and 102b further include the scattering layer 100 between the substrate 13 and the fluorescent layers 29a and 29b.

Portions (a) and (b) of FIG. 12 show exemplary combinations with Embodiment 3. Wavelength conversion elements 103a and 103b include the respective fluorescent layers 39a and 39b in which the first particles (phosphor particles) 10 and 20 and the second particles 31 that are smaller than the first particles 10 and 20 are dispersed in the binder 12, as in Embodiment 3. The second particles 31 scatter incident light. The wavelength conversion elements 103a and 103b further include the scattering layer 100 between the substrate 13 and the fluorescent layers 39a and 39b.

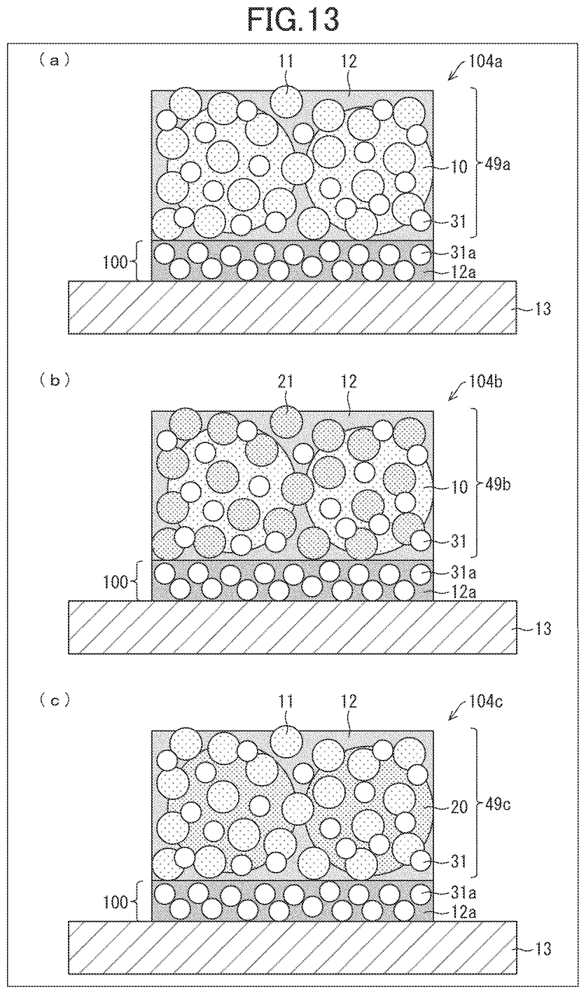

Portions (a), (b), and (c) of FIG. 13 show exemplary combinations with Embodiment 4. Wavelength conversion elements 104a, 104b, and 104c include the respective fluorescent layers 49a, 49b, and 49c in which the first particles (phosphor particles) 10 and 20, the second particles 11 and 21 that are smaller than the first particles 10 and 20, and the third particles 31 that are smaller than the second particles 11 and 21 are dispersed in the binder 12, as in Embodiment 4. The third particles 31 scatter incident light. The wavelength conversion elements 104a, 104b, and 104c further include the scattering layer 100 between the substrate 13 and the fluorescent layers 49a, 49b, and 49c.

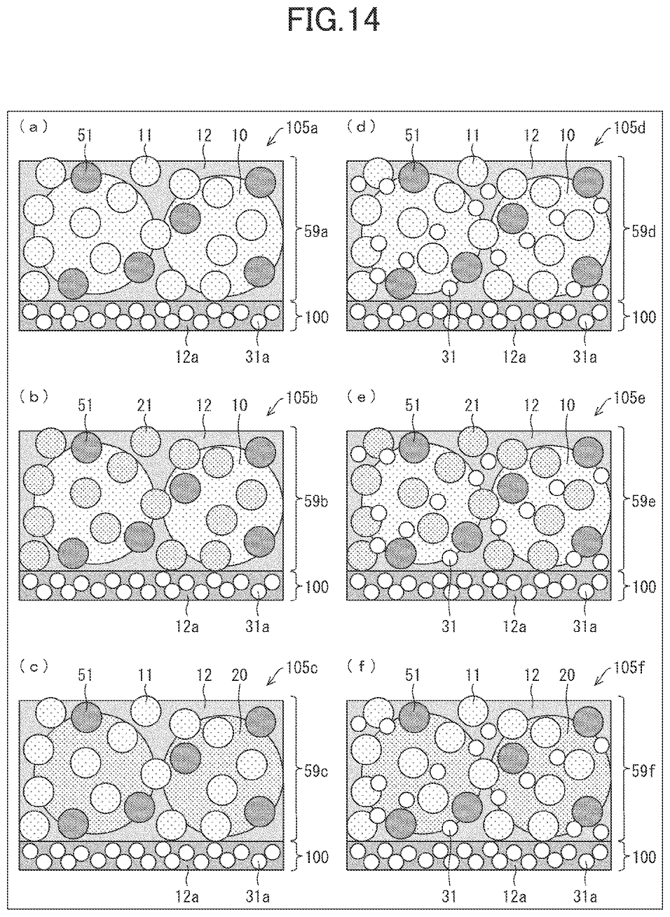

Portions (a) to (f) of FIG. 14 show exemplary combinations with Embodiment 5. Wavelength conversion elements 105a, 105b, and 105c include the respective fluorescent layers 59a, 59b, and 59c in which the first particles (phosphor particles) 10 and 20, the second particles 11 and 21 that are smaller than the first particles 10 and 20, and the fourth particles 51 that are smaller than the first particles 10 and 20 are dispersed in the binder 12, as in Embodiment 5. The fourth particles 51, under light that has the same wavelength as the incident light, fluoresce at different wavelengths from the wavelengths of the emission by the first particles 10 and 20. The wavelength conversion elements 105a, 105b, and 105c further include the scattering layer 100 between the substrate 13 (not shown) and the fluorescent layers 59a, 59b, and 59c.

Wavelength conversion elements 105d, 105e, and 105f include the respective fluorescent layers 59d, 59e, and 59f in which the first particles (phosphor particles) 10 and 20, the second particles 11 and 21 that are smaller than the first particles 10 and 20, the third particles 31 that are smaller the second particles 11 and 21, and the fourth particles 51 that are smaller than the first particles 10 and 20 are dispersed in the binder 12, as in Embodiment 5. The third particles 31 scatter incident light. The fourth particles 51, under light that has the same wavelength as the incident light, fluoresce at different wavelengths from the wavelengths of the emission by the first particles 10 and 20. The wavelength conversion elements 105d, 105e, and 105f further include the scattering layer 100 between the substrate 13 (not shown) and the fluorescent layers 59d, 59e, and 59f.

The aspects of the invention shown in FIGS. 11 to 14, can further enhance scattering inside the fluorescent layers 19a, 29a, 29b, 39a, 39b, 49a, 49b, 49c, 59a, 59b, 59c, 59d, 59e, and 59f, thereby further improving fluorescent extraction efficiency for the surface struck by incident light.

The scattering layer 100 shown in FIGS. 11 to 14 may be disposed on the substrate 13. Alternatively, the scattering layer 100 may be disposed on the substrates 33a to 33c having a groove formed therein as shown in FIG. 3. The wavelength conversion elements 101a, 102a, 102b, 103a, 103b, 104a, 104b, 104c, 105a, 105b, 105c, 105d, 105e, and 105f may be mounted to the light source device 1 shown in FIG. 4.

### Embodiment 7

The following will describe another embodiment of the disclosure. For convenience of description, members of the present embodiment that have the same function as members of the preceding embodiments are indicated by the same reference numerals, and description thereof is not repeated.

### Structure of Light Source Device

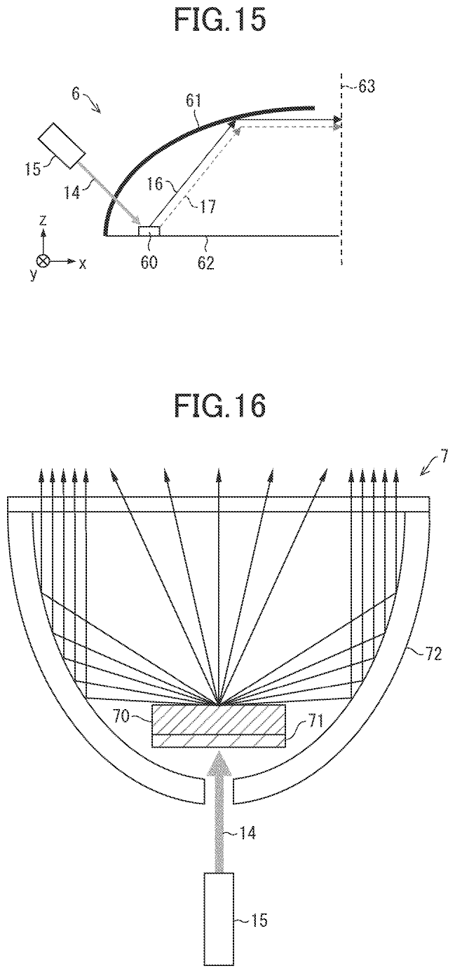

FIG. 15 is a schematic diagram of a light source device 6 in accordance with Embodiment 7 of the disclosure. The light source device 6 is a headlight (vehicle headlight) and preferably a reflective laser headlight.

An excitation light source 15 is preferably a blue laser source capable of emitting the excitation light 14 having such a wavelength as to excite a fluorescent layer in a wavelength conversion element 60. A reflector 61 preferably includes a semi-parabolic mirror. The reflector 61 preferably has a semi-paraboloid obtained by dividing a paraboloid into two upper and lower halves along a dividing face 62 that is parallel to the x-y plane. The reflector 61 preferably has an inner surface that can serve as a mirror. The reflector 61 has a through hole through which the excitation light 14 passes. The wavelength conversion element 60 is excited by the blue excitation light 14 to emit the fluorescence 16 having a longer visible wavelength (yellow wavelength). The excitation light 14 also forms the scattered/reflected light 17 upon impinging on a projection surface of the wavelength conversion element 60. The wavelength conversion element 60 is located at the focal point of the paraboloid on the dividing face 62. Since the wavelength conversion element 60 is located at the focal point of the paraboloid minor, the fluorescence 16 and the scattered/reflected light 17 emitted by the wavelength conversion element 60 are reflected by the reflector 61 and travel uniformly and straightly to an exit face 63. A mixture of the fluorescence 16 and the scattered/reflected light 17, which forms white parallel light, exits through the exit face 63.

In present Embodiment 7, the wavelength conversion element 60, which is located at the focal point of the paraboloid shown in FIG. 15, is preferably the wavelength conversion element 1a in accordance with Embodiment 1. The application of the wavelength conversion element 1a to Embodiment 6 enables further improved luminous efficiency over conventional art.

### Combinations with Other Embodiments

The wavelength conversion elements 1c to 1e in accordance with Embodiment 1, the wavelength conversion element 2a to 2b in accordance with Embodiment 2, the wavelength conversion element 3a to 3b in accordance with Embodiment 3, the wavelength conversion elements 4a to 4c in accordance with Embodiment 4, the wavelength conversion elements 5a to 5f in accordance with Embodiment 5, and the wavelength conversion elements 101a, 102a, 102b, 103a, 103b, 104a, 104b, 104c, 105a, 105b, 105c, 105d, 105e, and 105f in accordance with Embodiment 6 may be used in another preferred embodiment.

### Embodiment 8

The following will describe another embodiment of the disclosure. For convenience of description, members of the present embodiment that have the same function as members of the preceding embodiments are indicated by the same reference numerals, and description thereof is not repeated.

Structure of Light Source Device

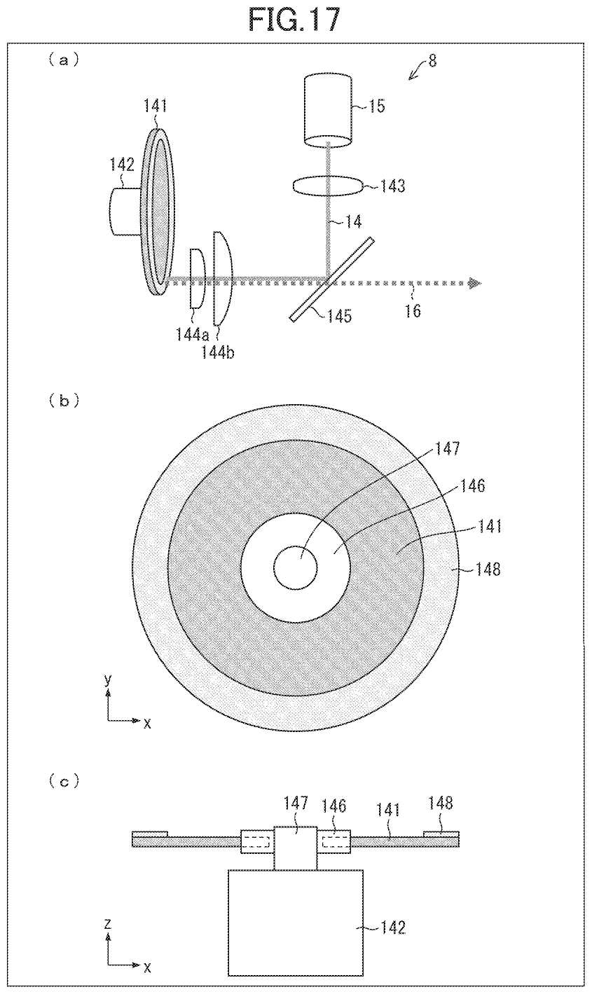

FIG. 16 is a schematic diagram of a light source device 7 in accordance with Embodiment 8 of the disclosure. The light source device 7 is a transmissive lighting device and preferably a transmissive laser headlight.

In a transmissive lighting device, the excitation light 14 is projected from the substrate side thereof for fluorescence. FIG. 16 shows an example where a wavelength conversion element 70 is disposed on a transmissive heatsink substrate 71. The excitation light 14 is projected from a face of the transmissive heatsink substrate 71 located opposite a face on which there is provided a fluorescent layer. The transmissive heatsink substrate 71 preferably serves as a heatsink. It is known that when a fluorescent layer is deposited on the transmissive heatsink substrate 71, and excitation light 14 enters from the heatsink side thereof, the heatsink side exhibits high heat dissipation.

The light emitted by the wavelength conversion element 70 causes fluorescence to exit through a face opposite the light-incident side. This fluorescence is reflected by a paraboloid 72 and exits the light source device 7 with high directionality.

In present Embodiment 8, the wavelength conversion element 70 shown in FIG. 16 is preferably the wavelength conversion element 1a in accordance with Embodiment 1. The application of the wavelength conversion element 1a to Embodiment 8 enables further improved luminous efficiency over conventional art.

### Combinations with Other Embodiments

In another preferred embodiment, the transmissive heatsink substrate 71 shown in FIG. 12 may be any one of the substrates 33a to 33c having a groove formed therein as shown in FIG. 3 described in Embodiment 1.

In yet another preferred embodiment, the wavelength conversion element 70 shown in FIG. 16 described in present Embodiment 8 may be any one of the wavelength conversion elements 1c to 1e in accordance with Embodiment 1, the wavelength conversion element 2a to 2b in accordance with Embodiment 2, the wavelength conversion element 3a to 3b in accordance with Embodiment 3, the wavelength conversion elements 4a to 4c in accordance with Embodiment 4, the wavelength conversion elements 5a to 5f in accordance with Embodiment 5, and the wavelength conversion elements 101a, 102a, 102b, 103a, 103b, 104a, 104b, 104c, 105a, 105b, 105c, 105d, 105e, and 105f in accordance with Embodiment 6.

### Embodiment 9

The following will describe another embodiment of the disclosure. For convenience of description, members of the present embodiment that have the same function as members of the preceding embodiments are indicated by the same reference numerals, and description thereof is not repeated.

### Structure of Light Source Device

Portion (a) of FIG. 17 shows a schematic diagram of a display device 8 in accordance with Embodiment 9 of the disclosure. A light source device 8 is suitably used, for example, in a projector including a fluorescent wheel 141.

The excitation light source 15 is preferably a blue laser source capable of emitting the excitation light 14 having such a wavelength as to excite a fluorescent layer 148. The excitation light source 15 is a blue laser diode capable of exciting a phosphor such as YAG or LuAG in a preferred embodiment. The excitation light 14 projected to the fluorescent layer 148 passes through lenses 143, 144a, and 144b on the optical path thereof. There may be provided a mirror 145 on the optical path of the excitation light 14. The mirror 145 is preferably a dichroic mirror.

### Structure of Fluorescent Wheel

Portion (b) of FIG. 17 shows a schematic plan view (x-y plane) of the fluorescent wheel 141 that can be mounted to the display device 8. Portion (c) of FIG. 17 shows a schematic side view (x-z plane) of the fluorescent wheel 141 that can be mounted to the display device 8.

The fluorescent layer 148 is provided on the fluorescent wheel 141. The fluorescent layer 148 is deposited on at least a part of the periphery of the surface of the fluorescent wheel 141 in a preferred embodiment. The fluorescent wheel 141 is fixed by a wheel fixing member 146 to a rotating shaft 147 of a driving device 142. The driving device 142 is preferably an electric motor, so that the fluorescent wheel 141 fixed by the fixing member 146 to the rotating shaft 147, which is a rotation shaft of the electric motor, can rotate with rotation of the electric motor.

The fluorescent layer 148, deposited on at least a part of the periphery of the surface of the fluorescent wheel 141, emits the fluorescence 16 under the excitation light 14. The fluorescence 16 passes through the mirror 145 and exits. Because the fluorescent layer 148 rotates with rotation of the fluorescent wheel 141, the fluorescent layer 148 emits the fluorescence 16 while rotating.

In present Embodiment 9, the fluorescent layer 148 shown in (b) and (c) of FIG. 17 is preferably the wavelength conversion element 1a (fluorescent layer 19a) in accordance with Embodiment 1. The application of the wavelength conversion element 1a to Embodiment 9 enables further improved luminous efficiency over conventional art.

### Combinations with Other Embodiments

In another preferred embodiment, the substrate of the fluorescent wheel 141 shown in FIG. 17 may be any one of the substrates 33a to 33c having a groove formed along the periphery of the surface of the fluorescent wheel 141 as shown in FIG. 3 described in Embodiment 1.

In yet another preferred embodiment, the fluorescent layer 148 shown in (b) and (c) of FIG. 17 in present Embodiment 9 may be a fluorescent layer in any one of the wavelength conversion elements 1c to 1e in accordance with Embodiment 1, the wavelength conversion element 2a to 2b in accordance with Embodiment 2, the wavelength conversion element 3a to 3b in accordance with Embodiment 3, the wavelength conversion elements 4a to 4c in accordance with Embodiment 4, the wavelength conversion elements 5a to 5f in accordance with Embodiment 5, and the wavelength conversion elements 101a, 102a, 102b, 103a, 103b, 104a, 104b, 104c, 105a, 105b, 105c, 105d, 105e, and 105f in accordance with Embodiment 6.

### Embodiment 10

The following will describe another embodiment of the disclosure. For convenience of description, members of the present embodiment that have the same function as members of the preceding embodiments are indicated by the same reference numerals, and description thereof is not repeated.

### Structure of Light Source Device

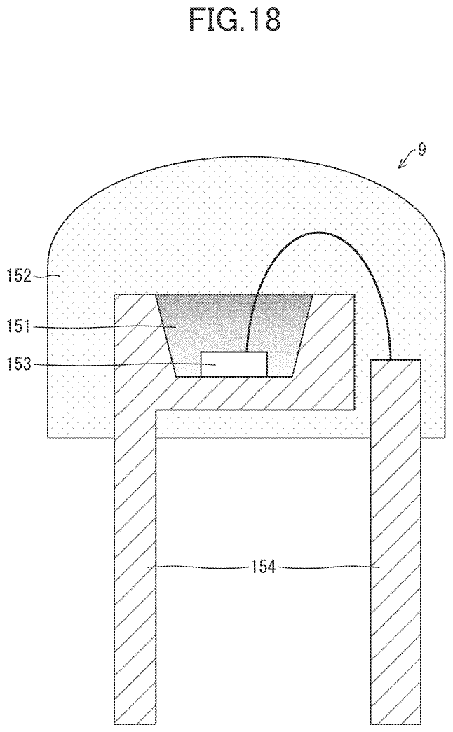

FIG. 18 is a schematic cross-sectional view of a light source device 9 in accordance with Embodiment 10 of the disclosure. The light source device 9 is a lighting device and preferably a bullet light-emitting diode (LED).

The light source device 9 includes: lead wires 154 at least partially constituting a pair of electrode terminals; and an excitation light source emitting the excitation light 14 and electrically connected to the pair of lead wires 154. The excitation light source is preferably a light-emitting diode (LED) element 153.

Referring to FIG. 18, the light-emitting diode (LED) element 153 is disposed on the bottom face of a concave in one of the pair of lead wires 154, with the main emission direction thereof pointing upwards. The concave is preferably formed in such a manner that the circumference of the light-emitting diode (LED) element 153 sitting on the bottom face of the concave is surrounded by an inclined surface that resembles the side face of a truncated cone. A wavelength conversion element is disposed inside the concave in such a manner as to cover the light-emitting diode (LED) element 153 sitting on the bottom face of the concave. The wavelength conversion element includes a fluorescent layer 151 onto which the excitation light 14 is projected from a first face (bottom face) side for extraction of the fluorescence 16 through a second face located opposite the first face.

Referring to FIG. 18, the light source device 9 is packaged on the second face (top face) of the fluorescent layer 151 with resin 152 in such a manner that the resin 152 can cover up the concave in the lead wire 154.

In present Embodiment 10, the fluorescent layer 151 shown in FIG. 18 is preferably the wavelength conversion element 1a (fluorescent layer 19a) in accordance with Embodiment 1. The application of the wavelength conversion element 1a to Embodiment 10 enables further improved luminous efficiency over conventional art.

### Combinations with Other Embodiments

In another preferred embodiment, the fluorescent layer 151 shown in FIG. 18 described in present Embodiment 10 may be a fluorescent layer in any one of the wavelength conversion element 2a to 2b in accordance with Embodiment 2, the wavelength conversion element 3a to 3b in accordance with Embodiment 3, the wavelength conversion elements 4a to 4c in accordance with Embodiment 4, the wavelength conversion elements 5a to 5f in accordance with Embodiment 5, and the wavelength conversion elements 101a, 102a, 102b, 103a, 103b, 104a, 104b, 104c, 105a, 105b, 105c, 105d, 105e, and 105f in accordance with Embodiment 6.

### General Description

The disclosure, in aspect 1 thereof, is directed to a wavelength conversion element that converts incident light from a wavelength range thereof to another wavelength range, the wavelength conversion element including a fluorescent layer including first particles and second particles dispersed in a first binder, the second particles being smaller than the first particles, wherein the first particles fluoresce under light having the wavelength of the incident light, and the first binder accounts for from 10% inclusive to 50% exclusive by volume of a particle group including the first particles and the second particles in the fluorescent layer.

The disclosure, in aspect 1 thereof, can improve the luminous efficiency of the fluorescent layer.

In aspect 2 of the disclosure, the wavelength conversion element of aspect 1 may be configured such that the first binder has a higher thermal conductivity than the first particles and the second particles.

The disclosure, in aspect 2 thereof, can restrain temperature rises in the fluorescent layer, thereby improving the luminous efficiency of the fluorescent layer.

In aspect 3 of the disclosure, the wavelength conversion element of aspect 1 or 2 may be configured such that the second particles fluoresce under light having the wavelength of the incident light.

The disclosure, in aspect 3 thereof, can improve the fill factor of the phosphor particles in the fluorescent layer, thereby improving the luminous efficiency of the fluorescent layer.

In aspect 4 of the disclosure, the wavelength conversion element of any one of aspects 1 to 3 may be configured such that the first particles and the second particles include a phosphor doped with a luminescence-center element, and the first particles are doped with luminescence-center atoms at a different concentration than are the second particles.

The disclosure, in aspect 4 thereof, can control temperature rises in the phosphor particles in the fluorescent layer, thereby improving the luminous efficiency of the fluorescent layer.

In aspect 5 of the disclosure, the wavelength conversion element of any one of aspects 1 to 4 may be configured such that the fluorescent layer further includes third particles dispersed in the first binder, the third particles being smaller than the first particles, the third particles scatter light having the wavelength of the incident light, and the particle group further includes the third particles.

The disclosure, in aspect 5 thereof, can improve fluorescent extraction efficiency for the fluorescent layer, thereby improving the luminous efficiency of the fluorescent layer.

In aspect 6 of the disclosure, the wavelength conversion element of aspect 1 or 2 may be configured such that the second particles scatter light having the wavelength of the incident light.

The disclosure, in aspect 6 thereof, can improve fluorescent extraction efficiency for the fluorescent layer, thereby improving the luminous efficiency of the fluorescent layer.

In aspect 7 of the disclosure, the wavelength conversion element of aspect 5 or 6 may be configured such that those particles that scatter light having the wavelength of the incident light have an average particle diameter smaller than the wavelength of the incident light.

The disclosure, in aspect 7 thereof, can improve the scattering properties of the scattering particles, thereby improving the luminous efficiency of the fluorescent layer.

In aspect 8 of the disclosure, the wavelength conversion element of any one of aspects 1 to 7 may be configured such that the fluorescent layer further includes fourth particles dispersed in the first binder, the fourth particles being smaller than the first particles, the fourth particles fluoresce by converting the incident light from the wavelength thereof to a wavelength different from a wavelength at which the first particles emit light, and the particle group further includes the fourth particles.

The disclosure, in aspect 8 thereof, can improve fluorescent extraction efficiency for the fluorescent layer and at the same time control temperature rises in the phosphor particles in the fluorescent layer, thereby improving the luminous efficiency of the fluorescent layer.

In aspect 9 of the disclosure, the wavelength conversion element of any one of aspects 1 to 8 may be configured such that the fluorescent layer is provided facing an underlying layer, the wavelength conversion element further includes a scattering layer between the underlying layer and the fluorescent layer, the scattering layer includes a second binder and scattering particles dispersed in the second binder, and the scattering particles have a higher refractive index than those particles that fluoresce under light having the wavelength of the incident light, the first binder, and the second binder.

The disclosure, in aspect 9 thereof, can increase the length of the optical path of excitation light, thereby improving the use efficiency of the excitation light.

In aspect 10 of the disclosure, the wavelength conversion element of any one of aspects 1 to 9 may be configured such that the first binder is composed primarily of an aluminum compound.

The disclosure, in aspect 10 thereof, can efficiently transfer heat, thereby improving the heat dissipation of the wavelength conversion element.

The disclosure, in aspect 11 thereof, may be directed to a light source device including: the wavelength conversion element of any one of aspects 1 to 10; and a light source that emits the incident light at the wavelength conversion element.

The disclosure, in aspect 11 thereof, can provide a light source device in which the fluorescent layer has an improved luminous efficiency.

The disclosure, in aspect 12 thereof, may be directed to a vehicle headlight including: the light source device of aspect 11; and a reflector having a reflection surface that reflects fluorescence emitted by the wavelength conversion element, wherein the reflection surface of the reflector reflects the fluorescence emitted by the wavelength conversion element so as to emit reflected fluorescence parallel to a predetermined direction.

The disclosure, in aspect 12 thereof, can provide a reflective vehicle headlight in which the fluorescent layer has an improved luminous efficiency.

The disclosure, in aspect 13 thereof, may be directed to a transmissive lighting device including: the light source device of aspect 11; and a transmissive substrate carrying the wavelength conversion element thereon, wherein the transmissive substrate has an irradiation surface irradiated by the light source and a surface opposite from the irradiation surface, the wavelength conversion element is disposed on the surface opposite from the irradiation surface of the transmissive substrate, the light source projects the incident light onto the wavelength conversion element through the transmissive substrate, and the fluorescent layer emits fluorescence through a surface opposite from an incident light side.

The disclosure, in aspect 13 thereof, can provide a transmissive lighting device in which the fluorescent layer has an improved luminous efficiency.

The disclosure, in aspect 14 thereof, may be directed to a display device including: a light source that emits incident light; a fluorescent wheel including the wavelength conversion element of any one of aspects 1 to 10 along at least a part of a circumferential direction in which the incident light emitted by the light source transmits; and a driving device that rotates the fluorescent wheel, wherein the display device emits fluorescence when the incident light strikes at least a surface of the wavelength conversion element as the fluorescent wheel rotates.

The disclosure, in aspect 14 thereof, can provide a display device in which the fluorescent layer has an improved luminous efficiency.

The disclosure, in aspect 15 thereof, may be directed to a lighting device including: a pair of electrode terminals; a light source electrically connected to the pair of electrode terminals, the light source being configured to emit incident light; and the wavelength conversion element of any one of aspects 1 to 10, wherein one of the pair of electrode terminals has therein a concave having a bottom face on which the light source is disposed with a main emission direction thereof pointing upwards, the concave is formed in such a manner that the light source sitting on the bottom face of the concave has a circumference thereof surrounded by an inclined surface that resembles a side face of a truncated cone, the wavelength conversion element is provided in the concave so as to cover the light source, the fluorescent layer has a first surface and a second surface on respective opposite sides thereof from each other in terms of a thickness direction, the first surface faces the light source side, and the fluorescent layer emits fluorescence through the second surface under the incident light striking the first surface.

The disclosure, in aspect 15 thereof, can provide a lighting device in which the fluorescent layer has an improved luminous efficiency.

The disclosure is not limited to the description of the embodiments above and may be altered within the scope of the claims. Embodiments based on a proper combination of technical means disclosed in different embodiments are encompassed in the technical scope of the disclosure. Furthermore, new technological features can be created by combining different technical means disclosed in the embodiments.

In aspect 16 of the disclosure, the wavelength conversion element of aspect 1 may be configured such that the first binder has a higher thermal conductivity than voids.

The disclosure, in aspect 16 thereof, can restrain temperature rises in the fluorescent layer, thereby improving the luminous efficiency of the fluorescent layer.

In aspect 17 of the disclosure, the wavelength conversion element of any one of aspects 1 to 9 may be configured such that the second binder is composed primarily of an aluminum compound.

The disclosure, in aspect 17 thereof, can efficiently transfer heat, thereby improving the heat dissipation of the wavelength conversion element.

1. A wavelength conversion element that converts incident light from a wavelength range thereof to another wavelength range, the wavelength conversion element comprising a fluorescent layer including first particles and second particles dispersed in a first binder, the second particles being smaller than the first particles, wherein
the first particles fluoresce under light having the wavelength of the incident light, and
the first binder accounts for from 10% inclusive to 50% exclusive by volume of a particle group including the first particles and the second particles in the fluorescent layer.

2. The wavelength conversion element according to claim 1, wherein the first binder has a higher thermal conductivity than the first particles and the second particles.

3. The wavelength conversion element according to claim 1, wherein the second particles fluoresce under light having the wavelength of the incident light.

4. The wavelength conversion element according to claim 1, wherein
the first particles and the second particles include a phosphor doped with a luminescence-center element, and
the first particles are doped with luminescence-center atoms at a different concentration than are the second particles.

5. The wavelength conversion element according to claim 1, wherein
the fluorescent layer further includes third particles dispersed in the first binder, the third particles being smaller than the first particles,
the third particles scatter light having the wavelength of the incident light, and
the particle group further includes the third particles.

6. The wavelength conversion element according to claim 1, wherein the second particles scatter light having the wavelength of the incident light.

7. The wavelength conversion element according to claim 5, wherein those particles that scatter light having the wavelength of the incident light have an average particle diameter smaller than the wavelength of the incident light.

8. The wavelength conversion element according to claim 1, wherein
the fluorescent layer further includes fourth particles dispersed in the first binder, the fourth particles being smaller than the first particles,
the fourth particles fluoresce by converting the incident light from the wavelength thereof to a wavelength different from a wavelength at which the first particles emit light, and
the particle group further includes the fourth particles.

9. The wavelength conversion element according to claim 1, wherein
the fluorescent layer is provided facing an underlying layer,
the wavelength conversion element further comprises a scattering layer between the underlying layer and the fluorescent layer,
the scattering layer includes a second binder and the scattering particles dispersed in the second binder, and
the scattering particles have a higher refractive index than those particles that fluoresce under light having the wavelength of the incident light, the first binder, and the second binder.

10. The wavelength conversion element according to claim 1, wherein the first binder is composed primarily of an aluminum compound.

11. A light source device comprising:
the wavelength conversion element according to claim 1; and
a light source that emits the incident light at the wavelength conversion element.

12. A vehicle headlight comprising:
the light source device according to claim 11; and
a reflector having a reflection surface that reflects fluorescence emitted by the wavelength conversion element, wherein
the reflection surface of the reflector reflects the fluorescence emitted by the wavelength conversion element so as to emit reflected fluorescence parallel to a predetermined direction.

13. A transmissive lighting device comprising:
the light source device according to claim 11; and
a transmissive substrate carrying the wavelength conversion element thereon, wherein
the transmissive substrate has an irradiation surface irradiated by the light source and a surface opposite from the irradiation surface,
the wavelength conversion element is disposed on the surface opposite from the irradiation surface of the transmissive substrate,
the light source projects the incident light onto the wavelength conversion element through the transmissive substrate, and
the fluorescent layer emits fluorescence through a surface opposite from an incident light side.

14. A display device comprising:
a light source that emits incident light;
a fluorescent wheel including the wavelength conversion element according to claim 1 along at least a part of a circumferential direction in which the incident light emitted by the light source transmits; and
a driving device that rotates the fluorescent wheel, wherein
the display device emits fluorescence when the incident light strikes at least a surface of the wavelength conversion element as the fluorescent wheel rotates.

15. A lighting device comprising:
a pair of electrode terminals;
a light source electrically connected to the pair of electrode terminals, the light source being configured to emit incident light; and
the wavelength conversion element according to claim 1, wherein
one of the pair of electrode terminals has therein a concave having a bottom face on which the light source is disposed with a main emission direction thereof pointing upwards,
the concave is formed in such a manner that the light source sitting on the bottom face of the concave has a circumference thereof surrounded by an inclined surface that resembles a side face of a truncated cone,
the wavelength conversion element is provided in the concave so as to cover the light source,
the fluorescent layer has a first surface and a second surface on respective opposite sides thereof from each other in terms of a thickness direction,
the first surface faces a side of the light source, and
the fluorescent layer emits fluorescence through the second surface under the incident light striking the first surface.
